(19) United States
(12) Patent Application Publication
(10) Pub. No.: US 2024/0204268 A1
(43) Pub. Date: Jun. 20, 2024

(54) Energy Storage Unit for an Electrical Consumer and Method for Manufacturing the Energy Storage Unit

(71) Applicant: Robert Bosch GmbH, Stuttgart (DE)

(72) Inventors: Holger Wernerus, Pliezhausen (DE); Andrej Stepanov, Filderstadt (DE); Christoph Klee, Stuttgart (DE)

(21) Appl. No.: 18/533,970

(22) Filed: Dec. 8, 2023

(30) Foreign Application Priority Data
Dec. 19, 2022 (DE) 10 2022 213 943.7

(51) Int. Cl. H01M 10/42; H01M 10/48; H05K 1/09; H05K 1/11; H05K 3/34; H05K 3/36

(52) U.S. Cl. CPC H01M 10/4257; H01M 10/486; H05K 1/09; H05K 1/111; H05K 3/341; H05K 3/368; H01M 2220/30; H05K 2201/041; H05K 2201/10151

(57) ABSTRACT

An energy storage unit for an electrical consumer includes at least one energy storage cell, a first printed circuit board for electrically contacting the at least one energy storage cell having a first and a second power supply contact of the energy storage unit. The first printed circuit board is arranged adjacent to the at least one energy storage cell and comprises at least one temperature sensor for sensing a temperature of the at least one energy storage cell. At least one further printed circuit board is electromechanically connected to the first printed circuit board and the at least one temperature sensor is arranged on the at least one further printed circuit board. The energy storage unit can be used with an electrical consumer such as a hand-held power tool with the energy storage unit designed as a removeable battery pack.

This application claims priority under 35 U.S.C. § 119 to application no. DE 10 2022 213 943.7, filed on Dec. 19, 2022 in Germany, the disclosure of which is incorporated herein by reference in its entirety.

The present disclosure relates to an energy storage unit for an electrical consumer and method for manufacturing the energy storage unit according to the disclosure.

### BACKGROUND

A large number of electrical consumers are operated using permanently integrated energy storage units (also referred to as rechargeable batteries or battery packs) or removeable energy storage units requiring no tool by the user (hereinafter referred to as removable battery packs), which are accordingly discharged by the electrical consumer and can be recharged using a charging device. Typically, such energy storage units consist of a plurality of energy storage cells interconnected in series and/or parallel in order to achieve a required battery voltage or capacity. A particularly advantageous high power and energy density can be achieved if the energy storage cells are, e.g., designed as lithium ion cells (Li-ion). On the other hand, in order to prevent electrical fault states, such cells also require adherence to tight specifications regarding the maximum charging and discharging current, voltage and temperature. If at least one of these operating parameters is outside of predetermined limit values, then the discharging or charging process of the energy storage unit is interrupted or at least restricted by the electronic system of the energy storage unit and/or the electrical consumer or charging device connected thereto. The temperature of the energy storage cells is thereby monitored by means of at least one temperature sensor, typically an NTC, which is in close thermal contact with at least one of the energy storage cells.

The object of the disclosure is to provide a measurement system in an energy storage unit for monitoring the temperature of at least one of the energy storage cells of the energy storage unit, which improves the thermal connectability of at least one temperature sensor of the measurement system compared to the prior art, and ensures low heat dissipation into the environment at low thermal capacity.

### SUMMARY

The disclosure relates to an energy storage unit for an electrical consumer comprising at least one energy storage cell, a first printed circuit board for electrically contacting the at least one energy storage cell using a first and a second power supply contact of the energy storage unit, the first printed circuit board being arranged adjacent to the at least one energy storage cell, and comprising at least one temperature sensor for sensing a temperature of the at least one energy storage cell. In order to achieve the above object, it is provided that at least one further printed circuit board is electromechanically connected to the first printed circuit board and that the at least one temperature sensor is arranged on the at least one further printed circuit board. A particularly advantageous thermal coupling between the at least one temperature sensor and the at least one energy storage cell being measured is in this way possible due to an optimal distance being achievable in a structurally related manner. For this purpose, the thickness of the at least one further printed circuit board, and optionally the height of the at least one temperature sensor, can be adapted independently of the first printed circuit board in order to achieve the optimum distance.

An optimum distance between the at least one temperature sensor and the at least one energy storage cell is achieved, on the one hand, when the distance is so small that a very advantageous thermal coupling is achieved, but, on the other hand, is so large that direct contact can be safely ruled out in order to exclude the risk of a short-circuit between the terminal pins of the at least one temperature sensor as a result of the at least one energy storage cell. In addition, a minimum distance between the at least one temperature sensor and the at least one energy storage cell prevents possible deformation of the at least one energy storage cell and/or damage to the at least one temperature sensor in the event of a fall or severe vibrations, in particular during use of the electrical consumer.

The expression “advantageous thermal coupling” is understood in particular to mean that there is a high thermal conductance of the transition from the at least one energy storage cell to the at least one temperature sensor. On the other hand, the thermal conductance of the transition from the at least one temperature sensor to its environment should be particularly low in order to prevent rapid cooling and, consequently, an incorrect measurement of the measuring system. In addition, an advantageous thermal coupling is characterized by a low thermal capacity of the measurement system for a fast response of the at least one temperature sensor.

The disclosure further relates to an electrical consumer comprising an energy storage unit according to the disclosure, and to a system consisting of an electrical consumer designed as a hand-held power tool and at least one electrical energy storage unit designed as an removeable battery pack. However, all devices that can be powered by an energy storage unit, e.g. a removeable battery pack or a permanently integrated battery pack, and comprising an electrical load are basically understood as an electrical consumer in the context of the disclosure. The electrical load can be designed as a predominantly inductive load in the form of an electromotive drive. Likewise, predominantly ohmic or capacitive loads are conceivable. Electrically commutated electric motors (referred to as EC or BLDC motors), the individual phases of which are controlled via at least one power transistor by pulse width modulation in order to control and/or regulate their speed and/or torque, are in particular suitable as electromotive drives. In this context, the disclosure can be applied to battery-powered machine tools for machining workpieces using an electrically driven insertion tool. The electrical machining device can be designed not only as a hand-held power tool, but also as a stationary machine tool. Typical machine tools in this context include hand-held or stationary drills, screwdrivers, impact drills, planers, angular grinders, oscillating sanders, polishing machines, or the like. However, suitable electrical consumers are also garden tools and construction equipment, e.g. lawn mowers, lawn trimmers, branch saws, tilling and trenching machines, blowers, robotic breakers and excavators, etc., as well as measuring devices, e.g. laser rangefinders, wall scanners, etc. The disclosure is also applicable to household appliances, e.g. vacuum cleaners, mixers, etc., and to electrically powered road and rail vehicles, e.g. e-bikes, e-scooters, pedelecs, electric and hybrid vehicles, etc., as well as to airplanes and ships comprising an energy storage unit according to the disclosure.

The voltage class of the energy storage unit results from the connection (in parallel or in series) of the individual energy storage cells integrated into the energy storage unit and is usually an integer multiple (>=1) of the voltage of the individual energy storage cells. An energy storage cell is typically designed as a galvanic cell comprising a structure in which a cell pole is arranged at an end face and another cell pole at an opposite end face. In particular, the energy storage cell comprises a positive cell pole at one end face and a negative cell pole at an opposite end face. Preferably, the energy storage cells are designed as lithium-based battery cells, e.g., Li-ion, Lipolymer, Li-metal, or the like. However, the disclosure can also be applied to energy storage units with Ni—Cd, Ni-Mh cells or other suitable cell types. In conventional Li-ion energy storage cells with a cell voltage of 3.6 V, voltage classes result of, e.g., 3.6 V, 7.2 V, 10.8 V, 14.4 V, 18 V, 36 V, etc. Preferably, an energy storage cells is designed as an at least substantially cylindrical round cell, the cell poles being arranged at ends of the cylindrical shape. However, the disclosure does not depend on the type and design of the energy storage cells used but can instead be applied to any energy storage units and energy storage cells, e.g., in addition to round cells, also to prismatic cells, pouch cells, or the like. The battery voltages are primarily based on the typical cell voltages of the energy storage cells being used. For example, regarding pouch cells and/or cells with other electrochemical compositions, voltage values that differ from those of the energy storage units equipped with Li-ion cells are possible.

If the energy storage unit is designed as an removeable battery pack, it can be releasably connected in a frictional or interlocking manner via an electromechanical interface of the removeable battery pack to a correspondingly complementary electromechanical interface of the electrical consumer or the charging device. The term “releasable connection” is understood in particular to mean a connection that can be released and established without a tool, i.e. manually. The design of the electromechanical interfaces and their receptacles for the frictional and/or interlocking releasable connection are not intended to be an object of the present disclosure. A skilled person will select an appropriate embodiment for the electromechanical interface depending on the power or voltage class of an electrical consumer and/or of an removeable battery pack, so this will not be explained in further detail. The embodiments shown in the drawings are therefore only to be understood by way of example. So, interfaces having more electrical contacts than illustrated can in particular also be used.

In a further embodiment, it is provided that the at least one further printed circuit board is arranged in the assembled state between the first printed circuit board and the at least one energy storage cell. The option of adapting the at least one further printed circuit board to the particular structural conditions of the energy storage unit makes it possible to reduce the manufacturing costs in series production and to optimize the distance between the at least one temperature sensor arranged on the further printed circuit board and the at least one energy storage cell being monitored such that, on the one hand, a very advantageous thermal coupling is achieved and, on the other hand, short-circuits can be reliably prevented.

A particularly simple connection of the further printed circuit board to the first printed circuit board that can be adapted to the local conditions is achieved if the at least one further printed circuit board comprises a plurality of flat edge metallizations and/or half-hole contacts, and the electromechanical connection to the first printed circuit board is made via bonded connections, in particular solder connections, of the flat edge metallizations and/or half-hole contacts using corresponding copper pads of the first printed circuit board. The copper pads of the first printed circuit board are designed such that they feature a tolerance range with respect to the edge metallizations and/or half-hole contacts of the at least one further printed circuit board. In this way, required position tolerances of the at least one further printed circuit board to the first printed circuit board can optionally be achieved. In addition, a fine adjustment of the at least one temperature sensor by a lateral displacement of the at least one further printed circuit board to the structural conditions of the at least one energy storage cell being measured is possible.

It is further provided that the at least one further printed circuit board, in particular as a function of the number of energy storage cells being monitored, bears a number of N>=1 temperature sensors and comprises a number M>=N+1 of flat edge metallizations and/or half-hole contacts. Typically, a temperature sensor comprises two terminal contacts, so that the at least one further printed circuit board must have a maximum of twice the number of M<=2N edge metallizations and/or half-hole contacts, provided that it does not bear any other electrical components other than the temperature sensors. However, it is also possible for N temperature sensors to each have one of their terminal contacts at a common potential, so only a single additional edge metallization and/or a single additional half-hole contact is required on the further printed circuit board.

A particularly cost-saving manufacture of the further printed circuit board results from the fact that the at least one further printed circuit board has a rectangular, square or honeycomb design and does not bear any further electrical components other than the at least one temperature sensor. The design can therefore be designed to be particularly compact to, on the one hand, save material costs and, on the other hand, minimize the heat capacity of the further printed circuit board. Furthermore, the rectangular, square or honeycomb design enables waste-free manufacture in what is referred to as printed circuit board panelization. In this context, a printed circuit board panelization is understood to be a series production in which a plurality of smaller printed circuit boards are manufactured from a large printed circuit board with standard dimensions under optimum surface utilization. Typically, the printed circuit board panel is not divided into the smaller printed circuit boards until after the individual components (in the specific case of the temperature sensors) have been assembled in an SMT (Surface Mounted Technology) or THT (Through Hole Technology) process. In this case, an NTC in the form of a surface mounted device (SMD) provides the additional benefit of a particularly small design space as well as a resulting reduction in heat capacity and manufacturing costs. Preferably, a plurality of edges of the further printed circuit board (for example, two of four edges in the case of a rectangular or square printed circuit board, or four of six edges in the case of a honeycomb-shaped printed circuit board) is also free of edge metallization and/or half-hole contacts, so that processing during the separation of the printed circuit board panel is simplified.

In one embodiment, it is provided that the at least one further printed circuit board comprises at least one first recess, which partially surrounds the at least one temperature sensor and/or is arranged in its immediate vicinity. In a particularly advantageous manner, the at least one first recess can further reduce the heat dissipation around the at least one temperature sensor during the temperature measurement as a result of the reduced thermal mass. In this context, a recess is understood to mean as a depression in the at least one further printed circuit board or a breakthrough or bore through the at least one further printed circuit board.

A further reduction in heat dissipation can be achieved by the at least one further printed circuit board having copper conductor tracks of low thickness, in particular <½ ounce, and/or low width, in particular <=200 μm, for electrical contacting of the at least one temperature sensor. The conductor tracks can additionally be extended, in particular in a meandering shape, in order to increase their thermal conductivity.

Preferably, a cell holder for the at least one energy storage cell comprises at least one recess for the at least one temperature sensor, which can be filled with a material, in particular a thermally conductive material. It is therefore possible to create a defined space for the at least one temperature sensor, which contains a correspondingly precisely definable amount of the material, in particular thermally conducting material, for an optimal heat transfer and a measurement of the temperature of the at least one energy storage cell with as little error as possible. Also, spatial separation to energy storage cells can be created by the recess, the temperature of which is not being sensed by the at least one temperature sensor. A thermally conductive paste with a high thermal conductivity and an advantageous electrical insulating capability is particularly suitable as a thermally conductive material. Alternatively, a gap filler with a lower thermal conductivity can also be used. The at least one recess can in turn be used as a depression or as a breakthrough or bore. A cell holder is in particular understood to mean a sub-housing or a comparable design of the energy storage unit, which fixes the at least one energy storage cell within a housing of the energy storage unit or the electrical consumer. Multiple energy storage cells are also often connected in series and/or in parallel to form what is referred to as a cell cluster in order to achieve a certain battery voltage and/or battery capacity. Such a cell cluster is then typically held together by a corresponding cell holder and can then be installed more easily within the energy storage unit. In addition, the cell holder provides better protection against external influences, e.g. impacts, vibrations, etc.

It is further provided that the at least one further printed circuit board comprises at least one further recess in the vicinity of the at least one temperature sensor for visually checking for the presence of a thermally conductive material between the at least one temperature sensor and the at least one energy storage cell.

In order to enable the assembly process of the further printed circuit board onto the first printed circuit board by means of what is referred to as a pick and place method, the at least one further printed circuit board comprises at least one free area >3 mm², in particular a circular free area with a diameter >2 mm. The particular advantage thereby is that the energy storage unit can be manufactured quickly and cost-efficiently.

The first printed circuit board comprises at least one recess which, in the assembled state of the at least one further printed circuit board, is arranged on the first printed circuit board in the area of the at least one temperature sensor. As a result the heat transfer between the first and the at least one further printed circuit board can be reduced. In addition, after the assembly consisting of the printed circuit boards has been assembled on the at least one energy storage cell, the recess makes it possible to visually check for the presence of the material, in particular a thermally conductive material, between the at least one temperature sensor and the at least one energy storage cell.

In addition, the first printed circuit board and/or the cell holder can have at least one projection in the area of the at least one assembled further printed circuit board to create a defined distance between the first printed circuit board and the at least one energy storage cell. This minimizes the impact of any tolerance fluctuations with regard to the thickness of the first printed circuit board and/or the cell holder.

In order to solve the aforementioned problem and to achieve the advantages already described, the disclosure also relates to a method for manufacturing an energy storage unit according to the disclosure comprising the following method steps, according to which:
the at least one temperature sensor is assembled, in particular soldered, on the at least one further printed circuit board in a bonded manner,
the at least one further printed circuit board is assembled, in particular soldered, on the first printed circuit board in a bonded manner,
a recess in the cell holder provided for the temperature sensor is filled with a material, in particular a thermally conductive material, and
the assembly consisting of the first and the at least one further printed circuit board is assembled such that only the at least one further printed circuit board and/or the at least one temperature sensor are immersed in the material, which is in particular a thermally conductive material.

In a further method step, the first printed circuit board is designed such that the copper pads for soldering to the further printed circuit board each feature a tolerance range enabling a fine adjustment of the further printed circuit board or the at least one temperature sensor assembled thereon in order to adapt to the structural conditions of the energy storage cells used in the energy storage unit.

Finally, in a method step of the method, the presence of the material, in particular the thermally conductive material, can be checked by the at least one further recess of the at least one further printed circuit board.

### BRIEF DESCRIPTION OF THE DRAWINGS

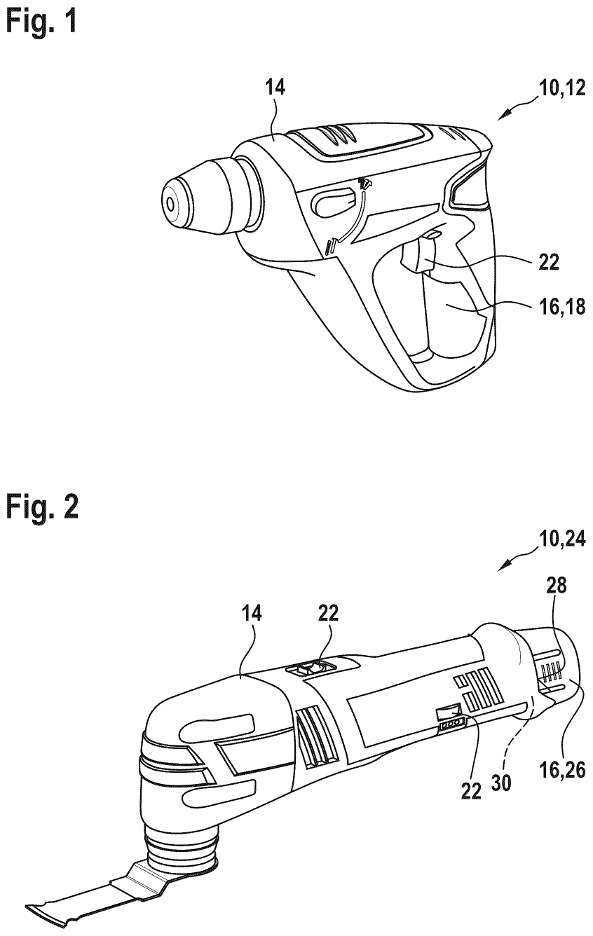

The disclosure is explained below with reference to FIGS. 1 through 9 by way of example, whereby identical reference numbers in the drawings indicate identical components having an identical function.

### Shown are:

FIG. 1: an electrical consumer designed as a hammer drill in the prior art in a perspective view,

FIG. 2: an electrical consumer designed as a multi-tool according to the prior art in a perspective view,

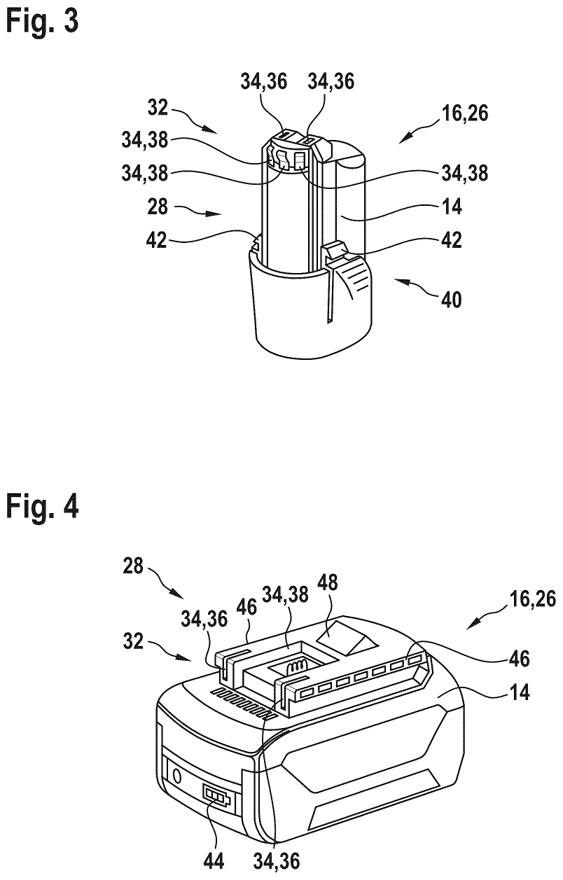

FIG. 3: an energy storage unit designed as a 12 V removeable battery pack according to the prior art in a perspective view,

FIG. 4: an energy storage unit designed as a 18 V removeable battery pack according to the prior art in a perspective view,

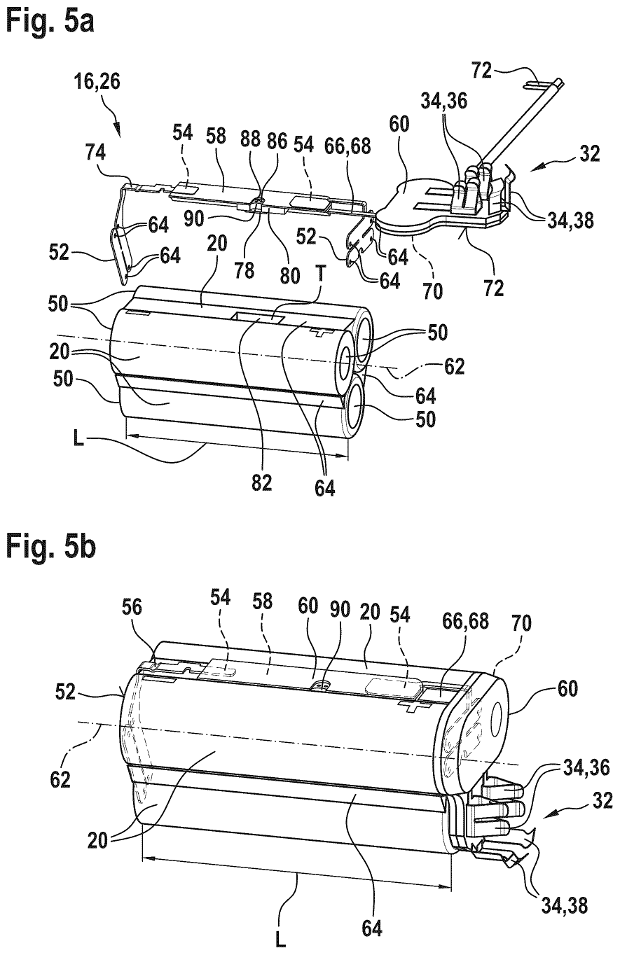

FIG. 5a: a first exemplary embodiment of an internal part of the 12 V removeable battery pack according to FIG. 3 in a perspective view before its assembly,

FIG. 5b: a first exemplary embodiment of an internal part of the 12 V removeable battery pack according to FIG. 3 in a perspective view after its assembly,

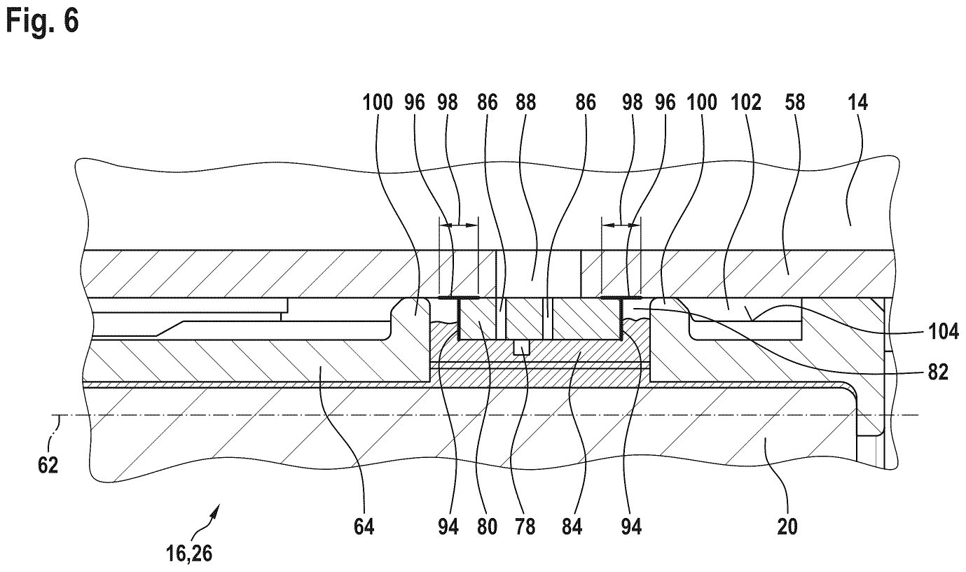

FIG. 6: a detailed view of a second embodiment of the energy storage unit in a section along its longitudinal axis in the area of a temperature sensor,

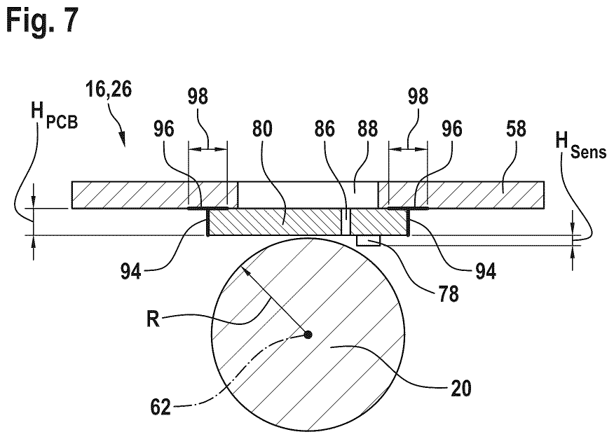

FIG. 7: a section through the energy storage unit transverse to its longitudinal axis in the area of the temperature sensor in a third embodiment,

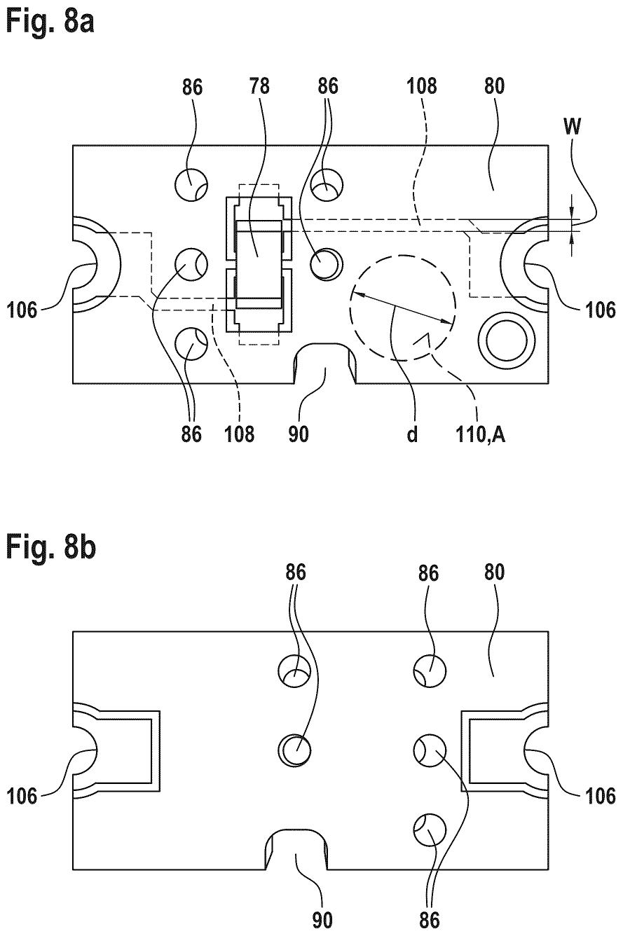

FIG. 8a: a further printed circuit board of the energy storage unit in a view from its assembled top in a fourth exemplary embodiment,

FIG. 8b: the further printed circuit board of the energy storage unit in a view from its unassembled bottom in the fourth exemplary embodiment, and

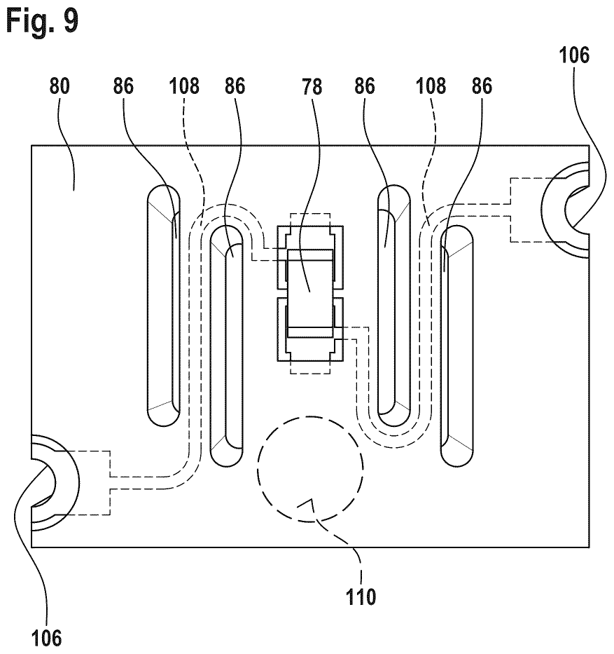

FIG. 9: the further printed circuit board of the energy storage unit in a view from its assembled top in a fifth embodiment.

### DETAILED DESCRIPTION

In FIG. 1, an electrical consumer 10 is shown by way of example, which is designed as a hammer drill 12 comprising a housing 14. In addition to a percussion mechanism (not shown in detail), which is driven by an electric motor (also not shown in detail), in particular a brushless DC motor (Electrically Commuted—EC, or Brushless Direct Current—BLDC), an energy storage unit 16 is arranged in the housing 14 of the hammer drill 12 for supplying energy to the electric motor and an electronic system (not shown) which controls said electric motor, whereby the energy storage unit 16 is designed as a permanently integrated battery pack 18 that cannot be replaced by the operator. The energy storage unit 16 can comprise an individual energy storage cell 20 or a plurality of energy storage cells 20 (see FIGS. 5a and 5b). As already mentioned hereinabove, the battery voltage U_{Batt} of the energy storage unit 16 generally results from an integer multiple (>=1) of the individual or cell voltages U_{cell} of the energy storage cells 20 as a function of their interconnection (parallel or serial). Preferably, the energy storage cells 20 are designed as lithium-based battery cells, e.g., Li-ion, Li-po, Li-metal, or the like. However, the disclosure can also be applied to energy storage units 20 with Ni—Cd, Ni-Mh cells, or other suitable cell types.

The speed and/or torque of the electric motor designed as an EC motor can, e.g., be controlled or regulated by means of the electronic system and an inverter (e.g., an H-bridge consisting of semiconductor switches, B6-bridge, or the like) controlled by pulse width modulation (PWM) as a function of a main switch 22. Given that the operation of a PWM drive is known to the skilled person, this will not be explained in further detail. In addition, other control or regulating methods for corresponding electric motors are also known without limiting the disclosure.

FIG. 2 shows a further exemplary embodiment for an electrical consumer 10 in the form of an electric motor-driven multi-tool 24. Instead of an individual main switch 22, it is divided into a pure on-off switch arranged on the top side of the housing 14 and a speed controller arranged laterally on the housing 14. A further significant difference to the hammer drill 12 shown in FIG. 1 is the interchangeability of the energy storage unit 16 designed as a removeable battery pack 26. For a connection to the multi-tool 24 that can be released without tools, i.e. by hand, the removeable battery pack 26 comprises an electromechanical interface 28 (see the following embodiments shown in FIGS. 3 and 4), which can be inserted into an electromechanical interface 30 of the multi-tool 24 designed as a plug-in holder. If the removeable battery pack 26 is fully inserted, it can supply the required battery voltage U_{Batt} to the multi-tool 26 or its electric motor and electronic system. An inserted removeable battery pack 26 is understood In particular to mean as a removeable battery pack 26 whose electromechanical interface 28 is connected to the correspondingly complementary electromechanical interface 30 of the electrical consumer 10 in the state connected to the electrical consumer 10.

It should be noted again that the disclosure can also be applied to electrical consumers featuring purely ohmic and/or capacitive electrical loads, so the electric power tools shown here are understood merely by way of example and are primarily intended to illustrate the different types of energy storage units 20 and their application.

In FIGS. 3 and 4, two different removeable battery packs 26 are shown in perspective views. In addition to their characteristic shape, the removeable battery packs 26 differ in particular in their battery voltage U_{Batt}, capacity and electromechanical interfaces 28.

FIG. 3 shows a removeable battery pack 26 comprising a battery voltage U_{Batt} of 10.8 V (nominal 12 V). The removeable battery pack 26 comprises a housing 14 in which three cylindrical energy storage cells 20 (see FIGS. 5 and 8) are arranged with a respective cell voltage U_{cell} of 3.6 V and electrically connected in series. The removeable battery pack 26 is designed such that it can be inserted into the electrical consumer 10 shown in FIG. 2, which is designed as a multi-tool 24, so that it can be released without tools.

The removeable battery pack 26 comprises an electrical contact part 32 of the electromechanical interface 28 at one end, the two electrical contacts 34 designed as power supply contacts 36, and three further electrical contacts 34 designed as signal and data contacts 38. On the one hand, the electrical consumer 10 or the multi-tool 24 can be supplied with power via the power supply contacts 36. On the other hand, it is also possible to charge the removeable battery pack 26 by means of a charging device not shown. Via the signal or data contacts 38, information on various operating parameters of the removeable battery pack 26, e.g. the battery voltage U_{Batt}, the cell voltages U_{Cell}, a temperature T measured in the removeable battery pack 26, a charging or discharging current I, a coding, or the like, can be transmitted to the electrical consumer 10 or the charging device for evaluation therein. Based on these operating parameters, the electronic system of the electrical consumer 10 or the charging device can control or regulate the discharging or charging process.

A mechanical contact part 40 is arranged on an end of the removeable battery pack 26 opposite the end comprising the electrical contact part 32 of the electromechanical interface 28 for the mechanical connection of the removeable battery pack 26 to the electrical consumer 10, which can be released without tools. The mechanical contact part 40 comprises two spring-loaded latching lugs 42 that can be connected in a frictional and an interlocking manner to the housing 14 of the electrical consumer 10. Generally, no corresponding latching is necessary in the charging device, so the latching lugs 42 are not used in that location. It is conceivable, however, that the removeable battery pack 26 is latched into the charging device during the charging process.

In FIG. 4, a removeable battery pack 26 comprising a battery voltage U_{Batt} of 18 V is shown. Ten cylindrical energy storage cells 20 are arranged in two layers in the housing 14 of the removeable battery pack 26. Two energy storage cells 20 each are connected in parallel to one cell cluster. The five cell clusters in total are then connected in series such that, at a cell voltage U_{Cell} of 3.6 V each, the resulting battery voltage U_{Batt} is 18 V. A charge state indicator 44 is arranged on the outer surface of the housing 14 of the removeable battery pack 26, via which the charge state can be displayed. The electromechanical interface 28 of the removeable battery pack 26 comprises two guide rails 46 that are guided into corresponding guide grooves of the electromechanical interface 30 of the electrical consumer 10 or the charging device when inserted. A locking element 48 is also provided, which is designed to lock the removeable battery pack 26 on the electrical consumer 10. The locking element 48 is designed as a pivotable and spring-mounted latching means that automatically latches at the end of the insertion operation. The inserted removeable battery pack 26 can be unlocked by actuating a mechanical actuating element (not shown) arranged on a side of the removeable battery pack 26 opposite the charging state indicator 44. The electrical contact part 32 of the electromechanical interface 28 is arranged between the two guide rails 46 and comprises a plurality of electrical contacts 34 for energy and data transmission according to the removeable battery pack 26 shown in FIG. 3. In particular, the signal or data contact 38 is designed as a coil, which transmits the operating parameters inductively to the electrical consumer 10. Accordingly, an electrical contact 34 is also understood to mean a contact that enables the contactless transmission of contactless energy and/or data.

FIG. 5a shows the inner part of the removeable battery pack 26 shown in FIG. 3 before its assembly. The removeable battery pack 26 comprises three Li-Ion energy storage cells 20 arranged such that their cross-section features a substantially triangular outer contour. Each energy storage cell 20 in turn comprises a positive and a negative cell pole 50 at its end faces. In FIG. 5b, the removeable battery pack 26 is shown after assembly of the inner part. In contrast to FIG. 3, the electrical contact part 32 of the electromechanical interface 28 only comprises two instead of three signal or data contacts 38. The three energy storage cells 20 are connected in series by means of two cell connectors 52 such that, at a cell voltage U_{cell} of 3.6 V each, the resulting battery voltage U_{Batt} is 10.8 V.

Each cell connector 52 is designed as a flat punched plate which, on the one hand, is electrically connected at a first end 54 to an electrical connection point 56 of a first printed circuit board 58 by means of a bonded connection, e.g. by soldering. The first printed circuit board 58 together with the components assembled thereon, the electrical connection points 56 and the ends 54 of the cell connectors 52 can optionally be cast using a potting compound 60, in particular completely, as shown in FIG. 5b. The potting compound 60 can, e.g., be formed from a low-pressure molding thermoplastic. In low-pressure molding, the assembled first printed circuit board 58 is inserted into a negative casting mold, which is then filled with a hot, viscous polymer. After the polymer has cooled, a robust and partially elastic shell is produced, which ensures very advantageous protection against corrosion caused by moisture, fingerprints, or the like. Alternatively, it is also conceivable that the potting compound 60 is formed from a silicone mass.

The first printed circuit board 58, optionally cast using a potting compound 60, is arranged parallel to a longitudinal axis 62 of the energy storage cells 20 on a cell holder 64. The cell holder 64 is used to fix the energy storage cells 20 within the housing 14 of the removeable battery pack 26 or the battery pack 18 permanently integrated into the electrical consumer 10 and is made of a non-electrically conductive material, for example plastic. In the example shown, three individual cell holders 64 are provided for the three energy storage cells 20. The three cell holders 64 can be integrally connected (i.e., a bonded connection) via corresponding external and/or internal bars or connections to form a single cell holder 64 (not shown). Likewise, it is conceivable that an individual cell holder 64 in the form of a sub-housing is used, into which the individual energy storage cells 20 can be inserted before their cell poles 50 are connected to the cell connectors 52. Particularly in larger removeable battery packs 26 (see FIG. 4), multiple energy storage cells 20 are also often connected in series and/or in parallel in this way to form what is referred to as a cell cluster in order to achieve a certain battery voltage and/or battery capacity. The energy storage cells 20 of each cell cluster are then typically mechanically fixed by the cell holder 64 designed as a sub-housing. Such a cell holder 64 also offers better protection of the energy storage cells 20 against external influences, e.g. impacts or vibrations, but also moisture or dirt, etc. Finally, the cell connectors 52, which are designed as flat punched plates or tabs (as shown in FIG. 5b) are connected in a bonded manner to the cell poles 50 of the energy storage cells 20 at the end of assembly of the inner part by means of resistance or cold welding via corresponding contact points 66.

The first printed circuit board 58 is electrically connected to at least one contact plate 72 by means of a flexible line 68, in particular a multi-core ribbon cable 70, which in turn is connected to two further punched plates 74. The two further punched plates 74 serve to electrically connect the positive cell pole 50 of the first energy storage cell 20 and the negative cell pole 50 of the last energy storage cell 20 of the series circuit with the positive or negative power supply contact 36 of the electromechanical interface 28. The two power supply contacts 36 are directly electromechanically connected in a bonded manner to the contact plate 72, e.g. by soldering, resistance or cold welding, but can also be electrically connected using corresponding cables. The same applies to the further punched plates 74. The first printed circuit board 58 and the contact plate 72 are finally arranged substantially perpendicular to each other around the energy storage cells 20 after the respective casting with the potting compound 60.

At least one of the cell connectors 52 comprises an SCM tap 76 for single cell monitoring, which is integrally connected to the cell connector 52 and is preferably arranged between the end 54 for electrical contact with the first printed circuit board 58 and the contact points 66 for electrical contacting the cell poles 50 of the energy storage cells 20. The SCM tap 76 is connected in a bonded manner, e.g. by soldering, to a cable, which in turn is connected to an SCM pre-stage (not shown) of a corresponding electronic system, which is arranged either in the removeable battery pack 26 or in the electrical consumer 10, if it comprises a permanently integrated battery pack 18, as shown in FIG. 1. To sense the individual cell voltages UCell, the SCM pre-stage switches sequentially between the individual SCM taps 76 of the cell connectors 52, e.g. via integrated transistors, such that it is connected to a positive and a negative cell pole 50 of the energy storage cell 20 or cell cluster being measured.

The electronic system of the removeable battery pack 26 or the electrical consumer 10 can have an integrated circuit in the form of a microprocessor, ASICs, DSPs, or the like to control or regulate the charging or discharging operation. It is also conceivable that the control or regulation occurs by means of several microprocessors or at least in part by means of discrete components comprising corresponding transistor logic. In addition, the electronic system can comprise a memory for storing the operating parameters. Given that this type of electronic system is known to the skilled person, this will not be explained further.

The temperature T of at least one of the energy storage cells 20 can be measured by means of a temperature sensor 78, which is preferably designed as an NTC and arranged in SMD design on a further printed circuit board 80, and evaluated by the electronic system of the removable battery pack 26 or of the electrical consumer 10 or of the charging device. For this purpose, the further printed circuit board 80 is arranged between the first printed circuit board 58 and the energy storage cell 20 in the assembled state, i.e. in particular with the temperature sensor 78 assembled. In this way, the distance between the temperature sensor 78 arranged on the further printed circuit board 80 and the energy storage cell 20 being monitored can be optimized such that, on the one hand, a very advantageous thermal coupling is achieved and, on the other hand, short circuits can be reliably prevented. In addition, a minimum distance between the temperature sensor 78 and the energy storage cell 20 prevents possible deformation of the energy storage cell 20 and/or damage to the temperature sensor 78 in the event of a fall or severe vibrations, in particular during use of the electrical consumer 10.

The cell holder 64, which fixes the energy storage cell 20 being monitored, comprises a recess 82 for the temperature sensor 78, which can be filled with a thermally conductive material 84, for example a thermally conductive paste or a gap filler (see FIG. 6). This results in a particularly advantageous thermal coupling between the temperature sensor 78 and the energy storage cell 20 being monitored due to the optimal distance between them that can be achieved due to design. The temperature sensor 78 is electrically connected via the further printed circuit board 80, which is electromechanically connected to the first printed circuit board 58, to one of the signal or data contacts 38 of the electromechanical interface 28 for transmitting the detected temperature T. In the case of a battery pack 18 permanently integrated into the electrical consumer 10, the temperature sensor 78 can also be connected directly to the electronic system of the electrical consumer 10 without a specific signal or data contact 38.

In order to manufacture the removeable battery pack 26, it is therefore necessary to first assemble, in particular to solder, the temperature sensor 78 onto the further printed circuit board 80 in a bonded manner in order to thereafter assemble, in particular to solder, the further printed circuit board 80 onto the first printed circuit board 58 in a bonded manner. The recess 82 provided for the temperature sensor 78 in the cell holder 64 is filled with a material 84, which is particularly thermally conductive, in order to finally assemble the assembly consisting of the first and the further printed circuit boards 58, 80 such that only the further circuit board 80 and/or the temperature sensor 78 is immersed in the material 84, which is in particular a thermally conductive material, (see also FIG. 6). For this purpose, the recess 82 of the cell holder 64 is designed as a depression.

The first printed circuit board 58, the further printed circuit board 80 and the temperature sensor 78 are preferably completely surrounded by the potting compound 60 as shown in FIG. 5b. For particularly advantageous thermal coupling of the temperature sensor 78 to the energy storage cell 20, the potting compound 60 is designed to be thermally conductive. To optimize the thermal conductivity between the temperature sensor 78 and the energy storage cell 20, the thermal contact area of the thermally conductive potting compound 60 is adapted to an outer contour of the energy storage cell 20. In the present exemplary embodiment, the energy storage cells 20 are designed as cylindrical round cells. An optimized thermal conductivity is therefore provided if the thermal contact surfaces of the thermally conductive potting compound 60 feature a complementary, concave shape in order to form as large a surface as possible, which transmits the temperature T of the energy storage cells 20 to the temperature sensor 78. In addition, such an interlocking connection enables simplified assembly of the cast first printed circuit board 58, since the correspondingly preformed potting compound 60 causes reproducible positioning on the energy storage cells 20. As mentioned hereinabove, other forms of energy storage cells 20 are conceivable as well. Accordingly, the thermal contact surfaces of the thermally conductive potting compound 60 should be designed to complement this.

FIG. 6 shows a detail view of the removeable battery pack 26 in a section along the longitudinal axis 62 in the area of the further printed circuit board 80 or of the temperature sensor 78 assembled thereon. The further printed circuit board 80 comprises a plurality of first recesses 86 designed as bores, which surround or are arranged in close proximity to the at least one temperature sensor 78. In a particularly advantageous manner, the first recess 86 can further reduce the heat dissipation around the temperature sensor 78 during the temperature measurement as a result of the reduced thermal mass.

The first printed circuit board 58 comprises a recess 88 which, in the assembled state of the at least one further printed circuit board 80, is arranged on the first printed circuit board 58 in the area of the at least one temperature sensor 78. As a result, the heat transfer between the first printed circuit board 58 and the further printed circuit board 80 can be reduced. In addition, after the assembly consisting of the printed circuit boards 58, 80 has been assembled on the energy storage cell 20, the recess 88 makes it possible to visually check for the presence of the thermally conductive material 84 between the temperature sensor 78 and the energy storage cell 20 being monitored. The visual check can be facilitated if the further printed circuit board 80 comprises a further recess 90 in the vicinity of the at least one temperature sensor 78, whereby the recess 88 of the first printed circuit board 58 and the further recess 90 of the further printed circuit board 80 are arranged directly adjacent to one another and are, e.g., designed as half-holes. If the assembly consisting of the first printed circuit board 58, the further printed circuit board 80, and temperature sensor 78 is surrounded by potting compound 60, then the potting compound 60 must also comprise a recess 92 for the visual check, which is positioned directly adjacent to the recess 88 of the first printed circuit board 58, as shown in FIG. 5b.

To achieve an electromechanical connection of the further printed circuit board 80 to the first printed circuit board 58, the further printed circuit board 80 comprises a plurality of flat edge metallizations 94 which are connected, in particular soldered, in a bonded manner to corresponding copper pads 96 of the first printed circuit board 58. The copper pads 96 of the first printed circuit board 58 are in this case designed such that they have a tolerance range 98 to the edge metallizations 94 of the further printed circuit board 58. In this way, required position tolerances of the further printed circuit board 80 to the first printed circuit board 58 can be achievable. A lateral fine adjustment of the temperature sensor 78 or the further printed circuit board 80 is thus possible such that the tolerance ranges 98 of the copper pads 96 are already adaptable to the structural conditions of the energy storage cells 20 used when designing the printed circuit board 80. In the case of a single temperature sensor 78 assembled on the further printed circuit board 80, M=2 edge metallizations 94 are required. However, it is also conceivable that further printed circuit board 80 bears a plurality of N>1 temperature sensors 78, e.g., to be able to monitor a plurality of energy storage cells 20 or an energy storage cell 20 at multiple locations. In this case, the number M of the flat edge metallizations 94 of the further printed circuit board is 80 M<=2N. Correspondingly, many copper pads 96 must then also be provided for the first printed circuit board 58. However, to facilitate processing during the separation of a printed circuit board panel, it is recommended that a plurality of edges of the further printed circuit board 80 be designed without edge metallizations 94.

In order to create a defined distance between the first printed circuit board 80 or the temperature sensor 78 assembled thereon and the energy storage cell 20, the cell holder 64 comprises two protrusions 100 in the area of the assembled further printed circuit board 80, which can minimize the impact of any tolerance fluctuations with respect to a thickness of the first printed circuit board 58 and/or the cell holder 64. The first printed circuit board 58 can also have a protrusion 102. However, in the exemplary embodiment shown, the protrusion 102 is primarily used to laterally align the first printed circuit board 58 on the cell holder 64 in conjunction with a corresponding recess 104 of the cell holder 64. As a result, a Poka-Yoke principle is also able to be achieved be achieved during assembly of the first printed circuit board 58. It is also conceivable that the protrusion 102 of the first printed circuit board 58 acts as a spacer corresponding to the protrusions 100 of the cell holder 64.

FIG. 7 shows a section through the energy storage unit 16 transverse to its longitudinal axis 62 in the area of the further printed circuit board 80 or the temperature sensor 78 in a highly simplified illustration. In contrast to FIG. 6, the copper pads 96 of the first printed circuit board 58 are arranged transversely to the energy storage cell 20 such that the edge metallizations 94 of the further printed circuit board 80 enable a corresponding fine adjustment of the temperature sensor 98 to adapt to the radius R of the energy storage cell 20 or its circumference. Also shown are the recesses 86 and 88 of the further and first printed circuit boards 80 and 58 as shown in FIGS. 5 and 6. The thickness HPCB of the further printed circuit board 80 can be adjusted independent of the first printed circuit board 58 to achieve the optimal distance between the temperature sensor 78 and the energy storage cell 20. This also applies in a similar manner to the component height H_{Sens} of the temperature sensor 78.

FIGS. 8a and 8b show an alternative embodiment of the further printed circuit board 80 in a view from a top side and equipped with temperature sensor 78 (FIG. 8a) operating according to assembly pressure and comprising a bottom side (FIG. 8b). The bottom side of the further printed circuit board 80 directly adjoins the first printed circuit board 58 in an assembled state. In contrast to the previous FIGS. 5 to 7, the further printed circuit board 80 comprises two half-hole contacts 106 instead of two edge metallizations 94, which are used in a similar manner for the electromechanical connection to the copper pads 96 of the first printed circuit board 58 via bonded connections, in particular solder connections. The electrical connection between the temperature sensor 78 and the two half-hole contacts 106 is achieved via a copper conductor track 108 in each case, which features an increased thermal conductivity to reduce the heat dissipation from the temperature sensor 78. For this purpose, the conductor tracks are designed with a low width W of in particular <=200 μm and/or a low thickness of in particular <½ oz.

In addition to the first recesses 86 formed as bores surrounding the temperature sensor 78 to improve heat dissipation, the further printed circuit board 80 comprises the further recess 90 formed as a half-hole in order to be able to visually check for the presence of the thermally conductive material 84 between the temperature sensor 78 and the energy storage cell 20 in the recess 82 of the cell holder 64 in a step of the manufacturing process.

In order to enable manufacturing as waste-free as possible in a printed circuit board panel, the further printed circuit board 80 is rectangular. However, other waste-free designs, e.g. a square or honeycomb design, are conceivable. In addition, the manufacture of the further printed circuit board 80 can be achieved in a particularly inexpensive and compact manner if the further printed circuit board 80 does not bear any further electrical components other than the at least one temperature sensor 78.

The assembly method of the further printed circuit board 80 onto the first printed circuit board 58 by means of what is referred to as a pick and place method is simplified if the further printed circuit board 80 comprises a circular free area 110 with a diameter >2 mm. Depending on the path of the conductive tracks 108 and/or the position of the temperature sensor 78 or the half-hole contacts 106 or the edge metallizations 94, other free surface shapes having a surface dimension of A>3 mm² are also conceivable.

In FIG. 9, a further embodiment of the further printed circuit board 80 is shown in a top plan view with the assembled temperature sensor 78. To reduce heat dissipation, the conductor tracks 108 from the two half-hole contacts 106 to the temperature sensor 78 are extended such that they are meandered around the recesses 86 designed as oblong holes to increase their thermal conductivity. Therefore, the recesses 86 and the conductor tracks 108 complement one another in their effect of reducing heat dissipation from the temperature sensor 78. Instead of a meandering path of the conductor tracks 108, it is also conceivable to have longer conductor tracks, for example circular, spiral or angular, with correspondingly suitable bending angles or the like. Likewise, the recesses 86 can feature differing shapes and can be designed as breakthroughs or depressions, as required. To facilitate the assembly process of the further printed circuit board 80 on the first printed circuit board 58, the free area 110 is provided as shown in FIG. 8a.

Finally, it should be noted that the exemplary embodiments shown are not limited to FIGS. 1 to 9, nor to the shape, number and size of the energy storage cells 20 and the further printed circuit board 80 of the energy storage unit 16. Accordingly, the number of temperature sensors 78 can also vary. In addition to NTC, PTC, and other types of temperature sensors 78 can also be used. Likewise, the disclosure is not limited to printed circuit boards 58, 80 having only one printed circuit board layer, but can also be applied to what are referred to as multi-layer PCBs. Finally, it is noted again that the disclosure is applicable not only to an energy storage unit 16 designed as an removeable battery pack 26, but also to a battery pack 18 integrated into an electrical consumer 10.

What is claimed is:

1. An energy storage unit for an electrical consumer, comprising:
at least one energy storage cell; and
a first printed circuit board configured to electrically contact the at least one energy storage cell using a first and a second power supply contact of the energy storage unit wherein the first printed circuit board is arranged adjacent to the at least one energy storage cell; and
at least one temperature sensor configured to sense a temperature of the at least one energy storage cell,
wherein at least one further printed circuit board is electromechanically connected to the first printed circuit board, and
the at least one temperature sensor is arranged on the at least one further printed circuit board.

2. The energy storage unit according to claim 1, wherein the at least one further printed circuit board is, in an assembled state, arranged between the first printed circuit board and the at least one energy storage cell.

3. The energy storage unit according to claim 1, wherein:
the at least one further printed circuit board comprises a plurality of flat edge metallizations and/or half-hole contacts; and
the electromechanical connection to the first printed circuit board is made via bonded solder connections, flat edge metallizations, and/or half-hole contacts using corresponding copper pads of the first printed circuit board.

4. The energy storage unit according to claim 3, wherein the copper pads of the first printed circuit board are designed such that they feature a tolerance range with respect to the edge metallizations and/or half-hole contacts of the at least one further printed circuit board.

5. The energy storage unit according to claim 3, wherein the at least one further printed circuit board bears a number N>=1 of temperature sensors and comprises a number M>=N+1 of flat edge metallizations and/or half-hole contacts.

6. The energy storage unit according claim 1, wherein the at least one further printed circuit board features a rectangular, square, or honeycomb design and bears no further electrical components other than the at least one temperature sensor.

7. The energy storage unit according to claim 1, wherein the at least one further printed circuit board comprises at least one first recess which partially surrounds the at least one temperature sensor and/or is arranged in the immediate vicinity thereof.

8. The energy storage unit according to claim 1, wherein the at least one further printed circuit board comprises conductor tracks made of copper of <½ ounce, and/or <=200 μm configured to electrically contact the at least one temperature sensor.

9. The energy storage unit according to claim 1, wherein a cell holder for the at least one energy storage cell comprises at least one recess for the at least one temperature sensor, which recess is configured to be filled with a thermally conductive material.

10. The energy storage unit according to claim 9, wherein the at least one further printed circuit board comprises at least one further recess in proximity to the at least one temperature sensor configured to enable a visual check for the presence of the thermally conductive material between the at least one temperature sensor and the at least one energy storage cell.

11. The energy storage unit according to claim 1, wherein the at least one further printed circuit board comprises at least one free surface of >3 mm², and a circular free surface with a diameter >2 mm.

12. The energy storage unit according to claim 1, wherein the first printed circuit board comprises at least one recess which, in the assembled state with the at least one further printed circuit board, is arranged on the first printed circuit board in the area of the at least one temperature sensor.

13. The energy storage unit according to claim 9, wherein the first printed circuit board and/or the cell holder, in the area of the at least one assembled further printed circuit board, comprises at least one protrusion configured to create a defined distance between the first printed circuit board and the at least one energy storage cell.

14. An electrical consumer comprising an energy storage unit according claim 1.

15. A system consisting of an electrical consumer designed as a hand-held power tool and at least one electrical energy store designed as an removeable battery pack according to claim 1.

16. A method for manufacturing an energy storage unit according to claim 1, comprising:
assembling the at least one temperature sensor by soldering the at least one temperature sensor on the at least one further printed circuit board in a bonded manner;
assembling the at least one further printed circuit board by soldering the at least one further printed circuit board on the first printed circuit board in a bonded manner;
providing a recess for the temperature sensor in a cell holder filled with a thermally conductive material; and
assembling the the first and the at least one further printed circuit board such that only the at least one further printed circuit board and/or the at least one temperature sensor are immersed in the thermally conductive material.

17. The method according to claim 16, further comprising:
providing the first printed circuit board with copper pads for soldering with the further printed circuit board; and
designing the first printed circuit board such that the copper pads provided for soldering with the further printed circuit board each have a tolerance range for lateral fine adjustment of the further printed circuit board.

18. The method according to claim 16, further comprising:
checking the presence of the thermally conductive material through a further recess of the at least one further printed circuit board.
